(19) United States
(12) Patent Application Publication
(10) Pub. No.: US 2025/0087541 A1
(43) Pub. Date: Mar. 13, 2025

(54) SEMICONDUCTOR PACKAGE

(71) Applicant: Samsung Electronics Co., Ltd., Suwon-si (KR)

(72) Inventor: Youngbae Kim, Suwon-si (KR)

(21) Appl. No.: 18/804,501

(22) Filed: Aug. 14, 2024

(30) Foreign Application Priority Data
Sep. 7, 2023 (KR) 10-2023-0118770

(51) Int. Cl. H01L 23/13; G02B 6/42; H01L 23/00; H01L 23/498; H01L 25/16; H10B 80/00

(52) U.S. Cl. CPC H01L 23/13; G02B 6/4204; G02B 6/4274; H01L 23/49833; H01L 23/49838; H01L 24/16; H01L 25/167; H01L 2224/16145; H01L 2224/16227; H01L 2924/1431; H01L 2924/1436; H10B 80/00

(57) ABSTRACT

A semiconductor package includes a package substrate that extends in a first direction, an interposer on an upper surface of the package substrate, where the interposer includes: a first substrate that includes a first portion having a first thickness in a second direction that is perpendicular to the first direction and a second portion having a second thickness in the second direction that is greater than the first thickness, and a plurality of first through vias that extend into the first substrate, a photonic IC chip on the first portion of the first substrate, where the photonic IC chip includes: a second substrate, a front insulation layer, an optical waveguide, an optical fiber, and a coupler, and a plurality of semiconductor chips on the second portion of the interposer.

### CROSS-REFERENCE TO RELATED APPLICATION

This application claims priority under 35 U.S.C. § 119 to Korean Patent Application No. 10-2023-0118770, filed on Sep. 7, 2023 in the Korean Intellectual Property Office (KIPO), the contents of which are herein incorporated by reference in their entirety.

### TECHNICAL FIELD

Example embodiments relate to a semiconductor package. More particularly, example embodiments relate to a semiconductor package having a semiconductor chip with a co-packaged optics including a photonic IC chip.

### BACKGROUND

In co-packaged optics (CPO) in which a photonic integrated circuit (PIC) and an electronic device such as an application-specific integrated circuit (ASIC) are integrated into a single package, an interposer may be applied to decrease a signal transmission path between the electronic device and the PIC and to increase a data transmission speed and a bandwidth. In this case, warpage may occur in the semiconductor package due to heat that is generated by large amounts of optical signals introduced from the PIC and a difference of a coefficient of thermal expansion (CTE) between a package substrate and the interposer. Additionally, due to the warpage, an alignment error between an optical fiber and an optical waveguide provided in the PIC may occur, thereby causing coupling losses.

### SUMMARY

Example embodiments provide a semiconductor package configured to reduce or prevent coupling losses by preventing warpage.

According to example embodiments, a semiconductor package includes a package substrate that extends in a first direction, an interposer on an upper surface of the package substrate, where the interposer includes: a first substrate that includes a first portion that having a first thickness in a second direction that is perpendicular to the first direction and a second portion having a second thickness in the second direction that is greater than the first thickness, and a plurality of first through vias that extend into the first substrate, a photonic IC chip on the first portion of the first substrate, where the photonic IC chip includes: a second substrate that includes a front surface and a backside surface opposite to the front surface, a front insulation layer that at least partially overlaps the front surface in the second direction, an optical waveguide in the front insulation layer, an optical fiber configured to transmit an optical signal to the optical waveguide, and a coupler configured to align the optical fiber and the optical waveguide in the first direction, and a plurality of semiconductor chips on the second portion of the interposer.

According to example embodiments, a semiconductor package includes a package substrate that includes a plurality of first upper pads that are on an upper surface of the package substrate and are spaced apart from each other in a first direction and a second direction that intersects the first direction, an interposer on the upper surface of the package substrate, where: the interposer includes a first substrate that includes a first portion and a second portion, the first portion of the first substrate having a first thickness in a third direction that is perpendicular to the first direction and the second direction, and the second portion having a second thickness in the third direction, a photonic IC chip on the first portion of the first substrate, where the photonic IC chip includes: a second substrate that includes a front surface and a backside surface that is opposite to the front surface, a front insulation layer that at least partially overlaps the front surface in the second direction, an optical waveguide in the front insulation layer, an optical fiber configured to transmit an optical signal to the optical waveguide, and a coupler configured to align the coupler and the optical waveguide in the first direction, and a plurality of electronic devices on the second portion of the interposer.

According to example embodiments, a semiconductor package includes a package substrate that extends in a first direction, an interposer on the package substrate, where the interposer includes a first substrate that includes a first portion having a first thickness in a second direction that is perpendicular to the first direction, where the first substrate includes a second portion having a second thickness in the second direction, and where the interposer includes a plurality of first through vias that extend into the first substrate, a photonic IC chip that is on the first portion of the interposer, where the photonic IC chip includes a second substrate that includes a front surface and a backside surface that is opposite to the front surface, where the photonic IC chip includes a plurality of second through vias that extend between the front surface and the backside surface, where the photonic IC chip further includes a front insulation layer that at least partially overlaps the front surface in the second direction and has a first refractive index, where the photonic IC chip further includes an optical waveguide that is in the front insulation layer and has a second refractive index that is greater than the first refractive index, where the photonic IC chip includes an optical fiber configured to transmit an optical signal to the optical waveguide, and where the photonic IC chip includes a coupler configured to align the coupler with the optical waveguide in the first direction, an electronic IC chip that is on the front insulation layer and spaced apart from the optical waveguide in the first direction, and a plurality of electronic devices on the second portion of the interposer.

According to example embodiments, a semiconductor package may include a package substrate, an interposer mounted on the package substrate, a photonic IC chip mounted on the interposer, an electronic IC chip mounted on the photonic IC chip and a plurality of electronic devices mounted on the interposer to be spaced apart from the photonic IC chip in a first direction.

The interposer may include a substrate providing a first portion having a first height (or first thickness) and a second portion having a second height (or second thickness). The first height of the first portion may be greater than the second height of the second portion. A photonic IC chip may be mounted on a first region where the first portion is provided.

Accordingly, the first portion of the interposer where the photonic IC chip is mounted may have a relatively greater structural stiffness. Additionally, warpage due to heat generated by an optical signal introduced from the photonic IC chip may be reduced, so coupling losses due to alignment error between an optical fiber and an optical waveguide may be prevented or reduced.

### BRIEF DESCRIPTION OF THE DRAWINGS

FIG. 1 is a cross-sectional view illustrating a semiconductor package in accordance with example embodiments.

FIG. 2 is an enlarged cross-sectional view illustrating the ‘A’ portion of FIG. 1.

FIG. 3 is an enlarged cross-sectional view illustrating the ‘B’ portion of FIG. 1.

FIG. 4 is a plan view illustrating the semiconductor package of FIG. 1.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device.

Hereinafter, example embodiments will be explained in detail with reference to the accompanying drawings.

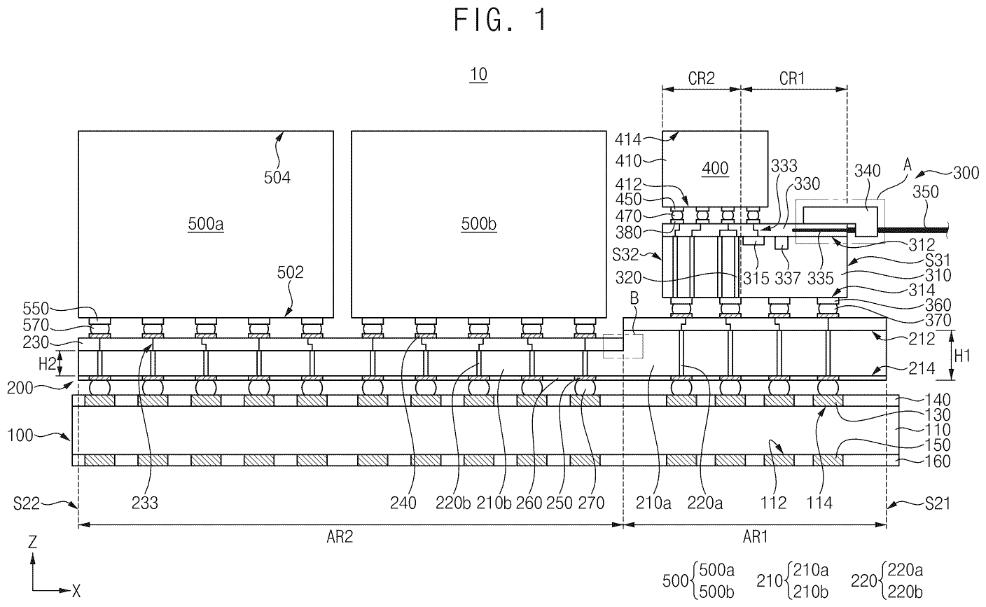

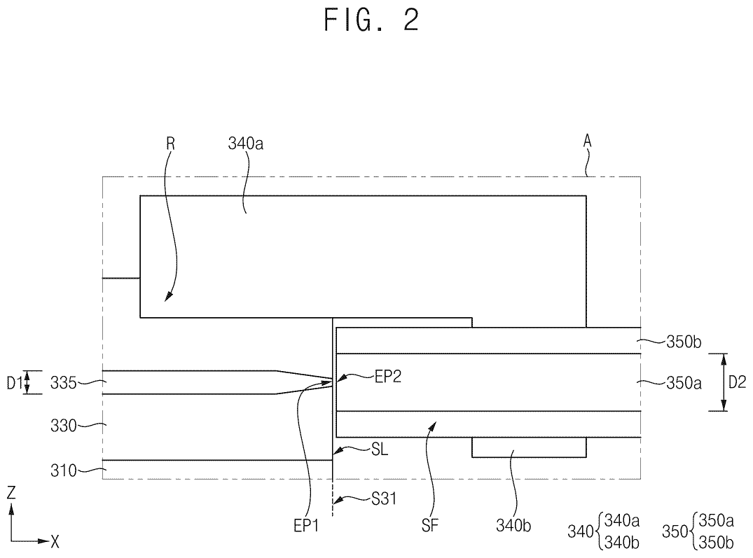

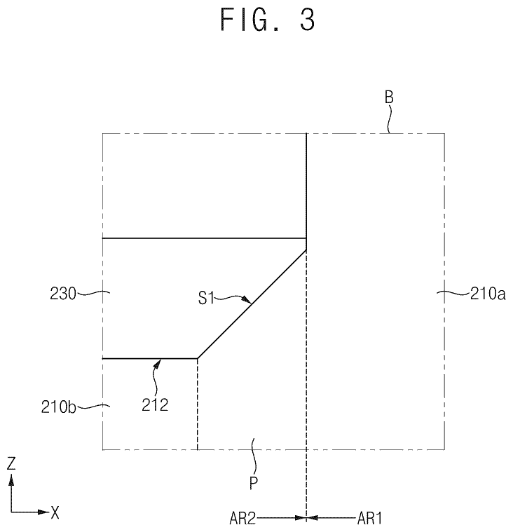

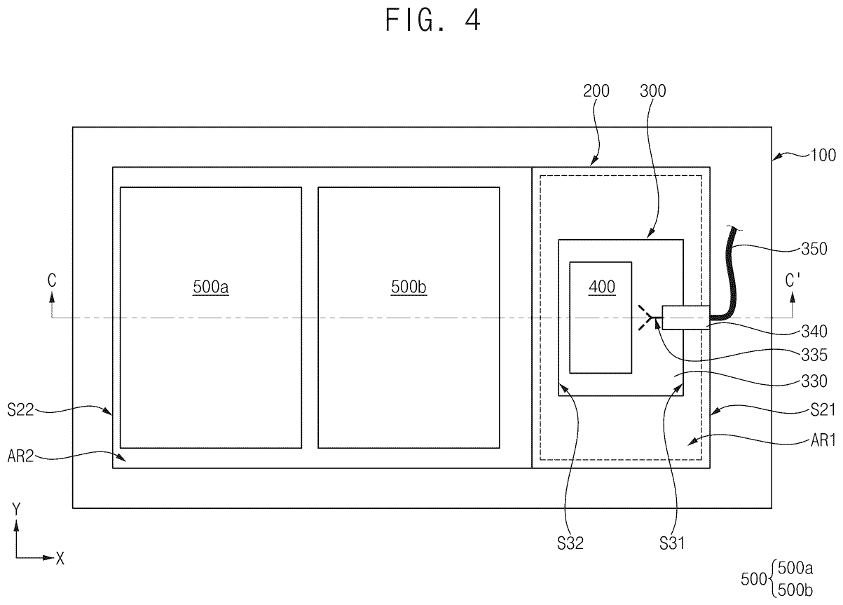

FIG. 1 is a cross-sectional view illustrating a semiconductor package in accordance with example embodiments. FIG. 2 is an enlarged cross-sectional view illustrating the ‘A’ portion of FIG. 1. FIG. 3 is an enlarged cross-sectional view illustrating the ‘B’ portion of FIG. 1. FIG. 4 is a plan view illustrating the semiconductor package of FIG. 1. FIG. 1 is a cross-sectional view taken along the line C-C′ in FIG. 4.

Referring to FIGS. 1 to 4, a semiconductor package 10 may include a package substrate 100, an interposer 200 stacked on the package substrate 100, a photonic IC chip 300 mounted on the interposer 200, an electronic IC chip 400 mounted on the photonic IC chip 300 and a plurality of electronic devices 500 mounted on the interposer 200. The plurality of electronic devices 500 may be spaced apart from the electronic IC chip 400 and the photonic IC chip 300 in a first direction (e.g., an X direction). Additionally, the semiconductor package 10 may further include first to fourth conductive connection members 270, 370, 470, and 570.

Additionally, the semiconductor package 10 may be a multi-chip package (MCP) including different types of semiconductor chips. The semiconductor package 10 may be a system in package (SIP) that has an independent function by stacking or arranging a plurality of semiconductor chips in one package. Additionally, the semiconductor package 10 may be co-packaged optics (CPO) including semiconductor chips and an optical module in one package. For example, the semiconductor package 10 may a co-packaged optics including a system in package (SIP) and an optical engine providing an electronic integrated circuit (EIC) and a photonic integrated circuit (PIC) in one package.

The plurality of electronic devices 500 may include a first electronic device 500a that includes a high bandwidth memory (HBM) device. Additionally, the plurality of electronic devices 500 may include a second electronic device 500b that includes a processor chip such as an ASIC as a host like CPU, GPU, or SOC, and an application processor (AP).

In example embodiments, the package substrate 100 may include a first substrate 110, a plurality of first upper pads 130, a first upper insulation layer 140, a plurality of first lower pads 150, and a first lower insulation layer 160.

The first substrate 110 may have a first surface 112 and a second surface 114 opposite to the first surface 112. For example, the first substrate 110 may include a plurality of insulation layers and a plurality of wirings. For example, the insulation layer may include an insulation material such as a thermosetting resin such as epoxy resin or a thermoplastic resin such as polyimide. The insulation layer may include a resin impregnated into a core material such as organic fiber (glass fiber), for example, prepreg, FR-4, or BT (Bismaleimide Triazine). For example, the wiring may include a metal material such as copper, aluminum, etc.

The plurality of first upper pads 130 may be disposed on the second surface 114 of the first substrate 110 and may be spaced apart from each other in the first direction (X direction). For example, the plurality of first upper pads 130 may be arranged on the second surface 114 in an array form including a plurality of columns and rows (e.g., the plurality of first upper pads 130 may be spaced apart from each other in the first direction (X direction) and a second direction (Y direction)). For example, the plurality of first upper pads 130 may be conductive pads including a metal material.

The first upper insulation layer 140 may cover or at least partially overlap the second surface 114 of the package substrate 100 in the third direction (Z direction) and may expose (or may not overlap or cover) at least a portion of each of the plurality of first upper pads 130.

The plurality of first lower pads 150 may be disposed on the first surface 112 of the first substrate 110 and may be spaced apart from each other in the first direction (X direction). For example, the plurality of first lower pads 150 may be arranged on the first surface 112 in an array form including a plurality of columns and rows (e.g., the plurality of first lower pads 150 may be spaced apart from each other in the first direction (X direction) and the second direction (Y direction)). For example, the plurality of first lower pads 150 may be conductive pads including a metal material.

The first lower insulation layer 160 may cover or at least partially overlap the first surface 112 of the package substrate 100 in a third direction (Z direction) and may expose (or may not overlap or cover) at least a portion of each of the plurality of first lower pads 150.

In example embodiments, the interposer 200 may include a second substrate 210, a plurality of first through vias 220, a first front insulation layer 230, a plurality of second upper pads 240, a plurality of second lower pads 250 and a backside insulation layer 260. Additionally, the interposer 200 may include a plurality of first conductive connection members 270. The interposer may be a silicon interposer having a plurality of wirings formed therein. Electronic devices mounted on the interposer may be electrically connected to each other through a plurality of first wirings 233. The interposer 200 may provide high-density interconnection between the electronic devices mounted on the interposer 200. Alternatively, the interposer 200 may be a redistribution interposer including a plurality of wirings, a plurality of metal vias, and a plurality of insulation layers.

The second substrate 210 may have a front surface 212 and a backside surface 214 extending in the first direction (X direction). The second substrate 210 may have a first side portion S21 extending in a second direction (Y direction) perpendicular to the first direction (X direction) and a second side portion S22 opposite to the first side portion S21. The second substrate may include a semiconductor material such as silicon, germanium, silicon-germanium, or a group III-V compound semiconductor such as gallium phosphide (GaP), gallium arsenide (GaAs), or gallium antimonide (GaSb).

The second substrate 210 may include a first region AR1 adjacent to the first side portion S21 and a second region AR2 excluding the first region AR1. The second substrate 210 may include a first portion 210a having a first height H1 from the backside surface 214 in the third direction (Z direction) and a second portion 210b having a second height H2 from the backside surface 214 in the third direction (Z direction). It should be understood that the first height H1 and the second height H2 may also be referred to as a first thickness H1 and a second thickness H2, respectively. The first portion 210a may be provided in or be part of the first region AR1 adjacent to the first side portion S21. The second portion 210b may be provided in or be part of the second region AR2 adjacent to the second side portion S22.

As illustrated in FIG. 3, the second substrate 210 may have an inclined boundary portion P between the first portion 210a and the second portion 210b. For example, the second portion 210b may have the inclined boundary portion P in a side portion where the second portion 210b is in contact with the first portion 210a. The inclined boundary portion P may have an inclined surface S1 disposed on a portion of the front surface 212 where the second portion 210b and the first portion 210a are in contact with each other. The inclined boundary portion P may be a structure that is configured to prevent or reduce cracks due to a sudden height change between the first portion 210a and the second portion 210b.

The plurality of first through vias 220 may extend from the front surface 212 to the backside surface 214 of the second substrate 210 to penetrate or extend into the second substrate 210. At least a portion of each of the plurality of first through vias 220 may be exposed from the front surface 212 and the backside surface 214. For example, the plurality of first through vias may include a through silicon via (TSV).

The plurality of first through vias 220 may include a plurality of first conductive vias 220a and a plurality of second conductive vias 220b. The plurality of first conductive vias 220a may be provided in the first portion 210a of the second substrate 210. The plurality of second conductive vias 220b may be provided in the second portion 210b of the second substrate 210.

The first front insulation layer 230 may cover or at least partially overlap the front surface 212 of the second substrate 210 in the third direction (Z direction). For example, the first front insulation layer 230 may be stacked on the front surface 212 of the second substrate 210 to cover or at least partially overlap the first region AR1 and the second region AR2 in the third direction (Z direction). The first front insulation layer 230 may include a plurality of first wirings 233. For example, the plurality of first wirings 233 may include a metal material for electrical connection.

The plurality of second upper pads 240 may be arranged on the first front insulation layer 230 in an array form including a plurality of columns and rows (e.g., the plurality of second upper pads 240 may be spaced apart from each other in the first direction (X direction) and the second direction (Y direction)). Each of the plurality of second upper pads 240 and each of the plurality of first through vias 220 may be electrically connected to each other through the plurality of first wires 233. For example, first end portions of the plurality of first wirings 233 may be electrically connected to the plurality of first through vias 220, respectively. Additionally, second end portions of the plurality of first wirings 233 may be respectively electrically connected to the plurality of second upper pads 240. For example, the plurality of second upper pads 240 may be conductive pads including a metal material for electrical connection.

The plurality of second lower pads 250 may be provided on the backside surface 214 of the second substrate 210 in an array form including a plurality of columns and rows (e.g., the plurality of second lower pads 250 may be spaced apart from each other in the first direction (X direction) and the second direction (Y direction)). The plurality of second lower pads 250 may be provided on the plurality of first through vias 220. For example, the plurality of second lower pads 250 may be conductive pads including a metal material for electrical connection.

The backside insulation layer 260 may cover or at least partially overlap the backside surface 214 of the second substrate 210 in the third direction (Z direction). For example, the backside insulation layer 260 may be stacked on the backside surface 214 of the second substrate 210 and may expose at least portions of the plurality of second lower pads 250.

The interposer 200 may be mounted on the package substrate 100 via a plurality of first conductive connection members 270. The plurality of first conductive connection members 270 may be provided on the plurality of second lower pads 250 respectively. For example, the plurality of first conductive connection members 270 may be solder bumps including a metal material.

In example embodiments, the photonic IC chip 300 may include a third substrate 310, a plurality of second through vias 320, a second front insulation layer 330, a coupler 340, an optical fiber 350, a plurality of third lower pads 360, a plurality of second conductive connection members 370, and a plurality of third upper pads 380. For example, the photonic IC chip 300 may be a photonic integrated circuit (PIC). The PIC may be an optical chip that includes a plurality of optical elements that detect and transmit optical signals, convert the optical signals into electrical signals, and process the optical signals.

The photonic IC chip 300 may be mounted on the first region AR1 of the interposer 200. For example, the photonic IC chip 300 may be mounted on the first front insulation layer 230 of the interposer 200 by a flip chip bonding method. For example, the photonic IC chip 300 may be mounted on the first region AR1 of the interposer 200 via a plurality of second conductive connection members 370 that are respectively provided between the plurality of second upper pads 240 and the plurality of third lower pads 360.

The third substrate 310 may have a front surface 312 and a backside surface 314 opposite to the front surface 312. The third substrate 310 may include a first side portion S31 extending in the second direction (Y direction) and a second side portion S32 opposite to the first side portion S31. A plurality of electronic elements 315 and a plurality of optical elements 337 may be provided on the front surface 312 of the third substrate 310. For example, the front surface 312 may be an active surface where the electronic elements and optical elements are formed. The photonic IC chip 300 may be mounted on the first front insulation layer 230 such that the backside surface 314 faces the interposer 200.

For example, the plurality of optical elements 337 may include laser diodes to generate optical signals, optical switches to manage a path of the optical signals, and optical modulators to transmit data by modulating the optical signals, photodetectors to convert the optical signals into electrical signals, etc. Accordingly, the plurality of optical elements 337 may convert optical signals introduced or received from the optical fiber 350 into electrical signals. For example, the plurality of electronic elements 315 may include electronic elements that process and transmit electrical signals converted from the plurality of optical elements 337.

The plurality of second through vias 320 may be provided in the third substrate 310 and may extend from the front surface 312 to the backside surface 314 of the third substrate 310 and penetrate or extend into the third substrate 310. For example, the plurality of second through vias 320 may be provided in the second connector region CR2 adjacent to the second side portion S32 of the third substrate 310. For example, the plurality of second through vias 320 may include a through silicon via (TSV).

The second front insulation layer 330 may cover or at least partially overlap the front surface 312 of the third substrate 310 in the third direction (Z direction). A plurality of second wirings 333 and an optical waveguide 335 may be provided in the second front insulation layer 330. For example, the plurality of second wirings 333 may be provided in the second connector region CR2 adjacent to the second side portion S32, and the optical waveguide 335 may be provided in the first connector region CRI adjacent to the first side portion S31. A first end portion of each of the plurality of second wirings 333 may be electrically connected to each of the plurality of second through vias 320 and the plurality of electronic elements 315. For example, the plurality of second wirings 333 may include a metal material for electrical connection.

For example, the optical waveguide 335 may be an optical path for transmitting an optical signal introduced or received from the optical fiber 350 into the plurality of optical elements 337. For example, the second front insulation layer 330 may be a cladding region with a relatively low refractive index, and the optical waveguide 335 may be a core region with a relatively high refractive index.

The coupler 340 may be provided on the second front insulation layer 330 adjacent to the first side portion S31. The coupler 340 may be a structure that is configured to secure the optical fiber 350. The coupler 340 may include a first coupling portion 340a and a second coupling portion 340b.

The first coupling portion 340a may be a portion where the coupler 340 is connected with a portion of the second front insulation layer 330. For example, the second front insulation layer 330 may have a recess R in a region adjacent to the first side portion S31. The first coupling portion 340a may be connected with the recess R of the second front insulation layer 330.

The second coupling portion 340b may be a portion that is configured to secure a portion of the optical fiber 350. For example, the portion of the optical fiber 350 may pass through or extend into the second coupling portion 340b to be fixed in an area adjacent to the first side portion S31 of the second front insulation layer 330.

As illustrated in FIG. 2, the optical fiber 350 may include a central portion 350a and a peripheral portion 350b at least partially surrounding the central portion 350a. The central portion 350a may be a core portion including a material with a relatively high refractive index. The peripheral portion 350b may be a cladding portion including a material with a relatively low refractive index and a coating portion at least partially surrounding the cladding portion.

The optical fiber 350 may be secured by the coupler 340 such that one end portion of the optical fiber 350 is adjacent to one side portion SL of the second front insulation layer 330. For example, the optical waveguide 335 may have a first end portion EP1 exposed from the side portion SL of the second front insulation layer 330. The central portion 350a of the optical fiber 350 may have a second end portion EP2 exposed from an end portion SF of the optical fiber 350. The first end portion EP1 and the second end portion EP2 may be aligned in the first direction (X direction).

The optical waveguide 335 may have a first diameter D1. The central portion 350a of the optical fiber 350 may have a second diameter D2. For example, the first diameter D1 may be less than the second diameter D2.

The plurality of third lower pads 360 may be provided on the backside surface 314 of the third substrate 310 in an array form along the XY direction (e.g., the plurality of third lower pads 360 may be spaced apart from each other in the first direction (X direction) and the second direction (Y direction)). For example, the plurality of third lower pads 360 may be conductive pads including a metal material for electrical connection.

The plurality of second conductive connection members 370 may be respectively provided on the plurality of third lower pads 360. For example, the plurality of third conductive connection members 370 may be solder bumps including a metal material.

The plurality of third upper pads 380 may be provided on the second front insulation layer 330 of the third substrate 310 to be adjacent to the second side portion S32 of the third substrate 310. For example, the plurality of third upper pads 380 may be in contact with a second end portion of each of the plurality of second wirings 333 opposite to the first end portion to be electrically connected to the plurality of second wirings 333. For example, the plurality of third upper pads 380 may be conductive pads for electrical connection.

In example embodiments, the electronic IC chip 400 may include a fourth substrate 410, a plurality of fourth lower pads 450, and a plurality of third conductive connection members 470. For example, the electronic IC chip 400 may be an electronic integrated circuit (EIC). For example, the EIC may convert an analog electrical signal introduced or received from the PIC into a digital electrical signal. Additionally, the EIC may be a semiconductor chip including electronic elements for converting an electrical signal of a current value into an electrical signal of a voltage value and amplifying the converted electrical signal.

The electronic IC chip 400 may be mounted on the second front insulation layer 330 of the photonic IC chip 300 to be adjacent to the second side portion S32 of the photonic IC chip 300. For example, the electronic IC chip 400 may be mounted on the photonic IC chip 300 using a flip chip bonding method. For example, the electronic IC chip 400 may be mounted on the second front insulation layer 330 via the plurality of third conductive connection members 470 that are respectively provided between the plurality of third upper pads 380 and the plurality of fourth lower pads 450.

For example, the fourth substrate 410 may have a front surface 412 and a backside surface 414 opposite to the front surface 412. The front surface 412 may be an active surface where the electronic elements are formed. For example, electronic IC chip 400 may be mounted on the photonic IC chip 300 such that that the front surface 412 faces the photonic IC chip 300.

The plurality of fourth lower pads 450 may be provided on the front surface 412 of the fourth substrate 410 in an array form along the XY direction (e.g., the plurality of fourth lower pads 450 may be spaced apart from each other in the first direction (X direction) and the second direction (Y direction)). For example, the plurality of fourth lower pads 450 may be conductive pads for electrical connection.

The plurality of third conductive connection members 470 may be provided on the plurality of fourth lower pads 450 respectively. For example, the plurality of third conductive connection members 470 may be solder bumps including a metal material.

In example embodiments, the plurality of electronic devices 500 may include the first electronic device 500a and the second electronic device 500b. Additionally, the plurality of electronic devices 500 may include a plurality of fifth lower pads 550 and a plurality of fourth conductive connection members 570. For example, the first electronic device 500a may include a memory device such as a high bandwidth memory (HBM), and the second electronic device 500b may include processor chips such as ASIC as a host like a CPU, GPU, and SOC, or an application processor (AP).

The plurality of electronic devices 500 may be mounted on the second region AR2 of the interposer 200 by a flip chip bonding method and may be spaced apart from the photonic IC chip 300 in the first direction (X direction). For example, the plurality of electronic devices 500 may be mounted on the second region AR2 of the interposer 200 via the plurality of fourth conductive connection members 570 that are respectively provided between the plurality of second upper pads 240 and the plurality of fifth lower pads 550.

The plurality of electronic devices 500 may sequentially mounted on the second region AR2 adjacent to the second side portion S22 of the interposer 200 to be spaced apart in the first direction (X direction).

For example, each of the plurality of electronic devices 500 may have a front surface 502 and a backside surface 504 opposite to the front surface 502.

The plurality of fifth lower pads 550 may be provided on the front surface 502 of the plurality of electronic devices 500 in an array form along the XY direction (e.g., the plurality of fifth lower pads 550 may be spaced apart from each other in the first direction (X direction) and the second direction (Y direction)). For example, the plurality of fifth lower pads 550 may be conductive pads for electrical connection.

A plurality of fourth conductive connection members 570 may be respectively provided on the plurality of fifth lower pads 550. For example, the plurality of fourth conductive connection members 570 may be solder bumps including a metal material.

As mentioned above, the semiconductor package 10 may include the package substrate 100, the interposer 200 stacked on the package substrate 100, the photonic IC chip 300 mounted on the interposer 200, the electronic IC chip 400 mounted on the photonic IC chip 300 and the plurality of electronic devices 500 mounted on the interposer 200 to be spaced apart from the photonic IC chip 300 in a first direction (e.g., X direction). Additionally, the semiconductor package 10 may further include the first to fourth conductive connection members 270, 370, 470, and 570.

The interposer 200 may include the second substrate 210 providing the first portion 210a having the first height H1 and the second portion 210b having the second height H2. The first height H1 of the first portion 210a may be greater than the second height H2 of the second portion 210b. The photonic IC chip 300 may be mounted on the first region AR1 where the first portion 210a is provided.

Accordingly, the first portion 210a of the interposer 200 where the photonic IC chip 300 is mounted may have a relatively higher structural stiffness. Additionally, warpage due to heat generated by an optical signal introduced or received from the photonic IC chip 300 may be reduced, so it is possible to prevent or reduce an alignment error between the second end portion EP2 of the optical fiber 350 and the first end portion EP1 of the optical waveguide 335. Thus, coupling losses due to the alignment error may be reduced or prevented.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A semiconductor package, comprising:
a package substrate that extends in a first direction;
an interposer on an upper surface of the package substrate, wherein the interposer comprises:
a first substrate that comprises a first portion having a first thickness in a second direction that is perpendicular to the first direction and a second portion having a second thickness in the second direction that is greater than the first thickness, and
a plurality of first through vias that extend into the first substrate;
a photonic IC chip on the first portion of the first substrate, wherein the photonic IC chip comprises:
a second substrate that comprises a front surface and a backside surface opposite to the front surface,
a front insulation layer that at least partially overlaps the front surface in the second direction,
an optical waveguide in the front insulation layer,
an optical fiber configured to transmit an optical signal to the optical waveguide, and
a coupler configured to align the optical fiber and the optical waveguide in the first direction; and
a plurality of semiconductor chips on the second portion of the interposer.

2. The semiconductor package of claim 1, wherein:
the interposer comprises a first side portion and a second side portion that is opposite the first side portion,
the first portion of the first substrate is adjacent to the first side portion, and
the second portion is of the first substrate is adjacent to the second side portion.

3. The semiconductor package of claim 1, wherein the first substrate of the interposer further comprises an inclined boundary portion that comprises an inclined surface between the first portion of the first substrate and the second portion of the first substrate.

4. The semiconductor package of claim 1, wherein:
the package substrate further comprises a plurality of first upper pads, the interposer further comprises a plurality of first lower pads that are on a first surface of the second substrate and are spaced apart from each other in the first direction and a third direction that intersects the first direction, and
the semiconductor package further comprises a plurality of conductive connection members that are respectively between the plurality of first upper pads and the plurality of first lower pads.

5. The semiconductor package of claim 1, wherein:
the photonic IC chip further comprises a plurality of chip pads that are on the backside surface of the second substrate and are spaced apart from each other in the first direction and a third direction that intersects the first direction,
the interposer further comprises a plurality of second upper pads that are on a second surface of the first substrate and are spaced apart from each other in the first direction and the third direction, and
the semiconductor package further comprises a plurality of second conductive connection members that are respectively between the plurality of second upper pads and the plurality of chip pads.

6. The semiconductor package of claim 1, wherein:
the photonic IC chip further comprises a first side portion and a second side portion that is opposite the first side portion,
the optical waveguide is adjacent to the first side portion of the photonic IC chip, and
the photonic IC chip further comprises a plurality of second through vias that are adjacent to the second side portion of the photonic IC chip and extend between the front surface of the second substrate and the backside surface of the second substrate.

7. The semiconductor package of claim 1, wherein a first refractive index of the front insulation layer is less than a second refractive index of the optical waveguide.

8. The semiconductor package of claim 1, further comprising:
an electronic IC chip that is on the front insulation layer of the photonic IC chip, wherein the plurality of semiconductor chips are adjacent to a first side of the electronic IC chip, and wherein the optical waveguide is adjacent to a second side of the electronic IC chip that is opposite to the first side of the electronic IC chip.

9. The semiconductor package of claim 1, wherein the optical fiber of the photonic IC chip comprises a central portion that defines a path of light and a peripheral portion that at least partially surrounds the central portion.

10. The semiconductor package of claim 9, wherein the coupler is further configured to align a first end portion of the optical waveguide with a second end portion of the central portion in the first direction.

11. A semiconductor package, comprising:
a package substrate that comprises a plurality of first upper pads that are on an upper surface of the package substrate and are spaced apart from each other in a first direction and a second direction that intersects the first direction;
an interposer on the upper surface of the package substrate, wherein:
the interposer comprises a first substrate that comprises a first portion and a second portion,
the first portion of the first substrate has a first thickness in a third direction that is perpendicular to the first direction and the second direction, and
the second portion has a second thickness in the third direction;
a photonic IC chip on the first portion of the first substrate, wherein the photonic IC chip comprises:
a second substrate that comprises a front surface and a backside surface that is opposite to the front surface,
a front insulation layer that at least partially overlaps the front surface in the second direction,
an optical waveguide in the front insulation layer,
an optical fiber configured to transmit an optical signal to the optical waveguide, and
a coupler configured to align the coupler and the optical waveguide in the first direction; and
a plurality of electronic devices on the second portion of the interposer.

12. The semiconductor package of claim 11, wherein the first thickness of the interposer is greater than the second thickness of the interposer.

13. The semiconductor package of claim 12, wherein:
the interposer further comprises a first side portion and a second side portion that is opposite to the first side portion, and
the photonic IC chip is adjacent to the first side portion, and
the plurality of electronic devices are adjacent to the second side portion.

14. The semiconductor package of claim 11, wherein:
the first substrate of the interposer comprises a first surface and a second surface opposite to the first surface,
the interposer further comprises a plurality of first lower pads that are on the second surface of the second substrate and are spaced apart from each other in the first direction and the second direction, and
the semiconductor package further comprises a plurality of first conductive connection members that are respectively between the plurality of first upper pads and the plurality of first lower pads.

15. The semiconductor package of claim 14, wherein the interposer further comprises a plurality of through vias that extend between the first surface of the first substrate and the second surface of the first substrate.

16. The semiconductor package of claim 11, wherein:
the photonic IC chip further comprises a plurality of chip pads that are on the backside surface of the second substrate and are spaced apart from each other in the first direction and the second direction,
the interposer further comprises a plurality of second upper pads that are on a first surface of the first substrate and are spaced apart from each other in the first direction and the second direction, and
the semiconductor package further comprises a plurality of second conductive connection members that are respectively between the plurality of second upper pads and the plurality of chip pads.

17. The semiconductor package of claim 11, wherein a first refractive index of the front insulation layer is less than a second refractive index of the optical waveguide.

18. The semiconductor package of claim 11, wherein the optical fiber of the photonic IC chip comprises a central portion that defines a path of light and a peripheral portion that at least partially surrounds the central portion.

19. The semiconductor package of claim 18, wherein the coupler is further configured to align a first end portion of the optical waveguide a second end portion of the central portion in the first direction.

20. A semiconductor package, comprising:
a package substrate that extends in a first direction;
an interposer on the package substrate, wherein the interposer comprises a first substrate that includes a first portion having a first thickness in a second direction that is perpendicular to the first direction, wherein the first substrate comprises a second portion having a second thickness in the second direction, and wherein the interposer comprises a plurality of first through vias that extend into the first substrate;
a photonic IC chip that is on the first portion of the interposer, wherein the photonic IC chip comprises a second substrate that comprises a front surface and a backside surface that is opposite to the front surface, wherein the photonic IC chip comprises a plurality of second through vias that extend between the front surface and the backside surface, wherein the photonic IC chip comprises a front insulation layer that at least partially overlaps the front surface in the second direction and has a first refractive index, wherein the photonic IC chip comprises an optical waveguide that is in the front insulation layer and has a second refractive index that is greater than the first refractive index, wherein the photonic IC chip further comprises an optical fiber configured to transmit an optical signal to the optical waveguide, and wherein the photonic IC chip further comprises a coupler configured to align the coupler with the optical waveguide in the first direction;
an electronic IC chip that is on the front insulation layer and spaced apart from the optical waveguide in the first direction; and
a plurality of electronic devices on the second portion of the interposer.
